(19) United States
(12) Patent Application Publication
(10) Pub. No.: US 2019/0177637 A1
(43) Pub. Date: Jun. 13, 2019

(54) SLIDING SYSTEM

(71) Applicant: TOYOTA JIDOSHA KABUSHIKI KAISHA, Toyota-shi (JP)

(72) Inventors: Hiroyuki MORI, Nagakute-shi (JP); Shigeru HOTTA, Nagakute-shi (JP); Mamoru TOHYAMA, Nagakute-shi (JP); Masaru OKUYAMA, Nagakute-shi (JP); Keiji HAYASHI, Nagoya-shi (JP); Kazuyoshi MANABE, Toyota-shi (JP)

(73) Assignee: TOYOTA JIDOSHA KABUSHIKI KAISHA, Toyota-shi (JP)

(21) Appl. No.: 16/186,686

(22) Filed: Nov. 12, 2018

(30) Foreign Application Priority Data
Dec. 12, 2017 (JP) 2017-238031

(51) Int. Cl. C10M 137/10; C23C 14/06; C10M 169/04

(52) U.S. Cl. CPC C10M 137/10; C23C 14/0641; C10N 2240/046; C10M 2203/003; C10M 2223/045; C10M 169/04

(57) ABSTRACT

[Technical Problem] An object is to provide a sliding system that allows the friction coefficient at a sliding part to be considerably reduced by means of a novel combination of a chromium nitride film and a lubricant oil.

[Solution to Problem] The sliding system of the present invention comprises: a pair of sliding members having sliding surfaces that can relatively move while facing each other; and a lubricant oil that can be interposed between the sliding surfaces facing each other. At least one of the sliding surfaces comprises a coating surface of a specific chromium nitride film, and the lubricant oil contains an oil-soluble molybdenum compound comprising molybdenum dialkyldithiophosphate (Mo-DTP). When the chromium nitride film as a whole is 100 at % (referred simply to as “%”), the chromium nitride film comprises 40-65% of Cr and 35-55% of N and has a relative surface area of 15-85%. The relative surface area is a surface area ratio of a (111) plane to a (200) plane obtained when analyzed with X-ray diffraction. The Mo-DTP is preferably contained at 150-800 ppm as a Mo mass content to the lubricant oil as a whole.

### TECHNICAL FIELD

The present invention relates to a sliding system that allows for reduction of the friction coefficient acting on sliding surfaces, etc., by means of a novel combination of the sliding surfaces and a lubricant oil.

### BACKGROUND ART

Various machines are provided with sliding members that relatively move while being slidably in contact with each other. In a system having such sliding members (referred to as a “sliding system” in the present description, e.g., a sliding machine), the resistance force (sliding resistance) acting on the sliding portions may be reduced thereby to enhance the performance and reduce the energy necessary for operation. Such reduction of the sliding resistance is ordinarily achieved by reducing the friction coefficient acting between the sliding surfaces.

The friction coefficient acting between the sliding surfaces differs depending on the surface condition of each sliding surface and the lubrication state between the sliding surfaces. To reduce the friction coefficient, therefore, it is conceivable to modify the sliding surfaces and improve the lubricant (lubricant oil) which is supplied between the sliding surfaces. Description relevant to the above is found, for example, in the following Patent Literature.

### PRIOR ART LITERATURE

### Patent Literature

### [Patent Literature 1] JP6114730B

### SUMMARY OF INVENTION

### Technical Problem

In the technique of Patent Literature 1, sliding surfaces coated with chromium nitride films are combined with a lubricant oil that contains an oil-soluble molybdenum compound comprising a Mo trinuclear, thereby to achieve both the low-friction property and the high wear resistance. The technique of Patent Literature 1, however, assumes that the lubricant oil may be an ordinary engine oil, so Patent Literature 1 only describes a specific friction property when the oil temperature is 80 C.°.

The present invention has been created in view of such circumstances, and an object of the present invention is to provide a sliding system that allows the friction coefficient to be reduced in a lower temperature region than that in the prior art, by means of a novel combination of a sliding film and a lubricant oil.

### Solution to Problem

As a result of intensive studies to solve the above technical problem, the present inventors have discovered that a novel combination of a specific chromium nitride film and a lubricant oil that contains Mo-DTP can reduce the friction coefficient between the sliding surfaces even in a low-temperature region. Moreover, it has also been found that such a low-friction property can be satisfied concurrently with the high wear resistance. Developing this achievement, the present inventors have accomplished the present invention as will be described hereinafter.

### «Sliding System»

(1) The sliding system of the present invention comprises: a pair of sliding members having sliding surfaces that can relatively move while facing each other; and a lubricant oil that can be interposed between the sliding surfaces facing each other. At least one of the sliding surfaces comprises a coating surface of a chromium nitride film. When the chromium nitride film as a whole is 100 at % (referred simply to as “%”), the chromium nitride film comprises 40-65% of Cr and 35-55% of N and has a relative surface area of 15-85%. The relative surface area is a surface area ratio of a (111) plane to a (200) plane obtained when analyzed with X-ray diffraction. The lubricant oil contains molybdenum dialkyldithiophosphate (referred simply to as “Mo-DTP”) that is an oil-soluble molybdenum compound. The Mo-DTP is contained at 125-800 ppm as a mass ratio of Mo with respect to the lubricant oil as a whole.

(2) The sliding surface coated with a specific chromium nitride film and the lubricant oil which contains Mo-DTP are combined thereby to allow a sliding system to be obtained which can reduce the friction coefficient between the sliding surfaces. According to the sliding system of the present invention, the sliding resistance and the friction loss can be reduced to allow for improvement in the motion performance of various machines, the energy conservation, and the like.

Moreover, the chromium nitride film according to the present invention can exhibit excellent wear resistance in addition to the low-friction property. The sliding system of the present invention is therefore suitable for machines and the like, such as in drive systems, which are operated for a long time under severe conditions from a boundary lubrication (friction) condition to a mixed lubrication (friction) condition.

For example, according to the sliding system of the present invention, the friction coefficient between the sliding surfaces can be 0.06 or less in an embodiment and 0.05 or less in another embodiment even when the temperature of the lubricant oil (referred simply to as an “oil temperature”) is 60° C. or lower in an embodiment and 50° C. or lower in another embodiment. Moreover, the sliding surface of the chromium nitride film can have a wear depth, which is indicative of the wear resistance, of ¼ or less in an embodiment and ⅙ or less in another embodiment as compared with that of a conventional sliding surface composed only of a steel material. Thus, the sliding system of the present invention is suitable for an internal-combustion engine for hybrid cars and/or a drivetrain (such as a transmission or a differential) in which increase in the oil temperature is moderate.

(3) The mechanism is not necessarily sure that the combination of a specific chromium nitride film and a Mo-DTP-containing lubricant oil according to the present invention develops the low-friction property and other advantageous properties, but under present circumstances, it can be considered as follows.

When the sliding system (specifically a sliding machine) of the present invention is operated, an adsorption reaction of the Mo-DTP contained in the lubricant oil is promoted on the sliding surface of the chromium nitride film. This appears to lead to suppression of adsorption between the Mo-DTP and additives such as Ca and Zn, so that a relatively large amount (large thickness) of a molybdenum sulfide compound of a MoS₂ structure is selectively adsorbed to the coating surface (sliding surface) of the chromium nitride film. This molybdenum sulfide compound of the MoS₂ structure has a lamellar structure and exhibits a low shear property. This appears to allow the friction coefficient to be reduced on the sliding surface of the chromium nitride film even under a wide variety of operational situations including the boundary friction.

The chromium nitride film according to the present invention is ordinarily harder than a base material (e.g. steel material) of the sliding member and less likely to transfer and adhere to the sliding surface of the counterpart sliding member. Accordingly, the sliding system of the present invention exhibits high wear resistance in the presence of the above-described lubricant oil, and an excellent low-friction property can be stably obtained for a long period of time.

(4) The chromium nitride film according to the present invention primarily comprises Cr and N, but may further contain, as additional elements, doped elements (e.g. O) and the like which do not inhibit the low-friction property or which improve the low-friction property. Cr and N in the chromium nitride film exist primarily as CrN, but a part thereof may be Cr₂N (dichromium nitride) or in other appropriate form. In consideration of the above, when the chromium nitride film as a whole is 100 at % (referred simply to as “%”), the chromium nitride film according to the present invention preferably comprises 40-65% of Cr and 35-55% of N in an embodiment and 45-62% of Cr and 38-50% of N in another embodiment.

The chromium nitride film may contain one or more doped elements. For example, the chromium nitride film may contain 1-15% of O and/or 0.5-5% of B in an embodiment and 5-13% of O and/or 1-3% of B in another embodiment. Such a film composition may be specified using an electron probe microanalyzer (EPMA).

The chromium nitride film according to the present invention may readily develop a low-friction property when having a specific crystal structure. To this end, the chromium nitride film according to the present invention preferably has a relative surface area of 15-85% in an embodiment, 20-80% in another embodiment, and 25-76% in still another embodiment. The relative surface area is a surface area ratio of a (111) plane to a (200) plane obtained when analyzed with X-ray diffraction. The surface area ratio (relative surface area) of each plane may be calculated by image analysis based on a profile obtained using X-ray diffraction.

### «Others»

(1) It suffices that the “sliding system” as referred to in the present invention comprises sliding members and a lubricant oil. The sliding system is not limited to being a completed product as a machine and may also be a combination of mechanical elements that constitute a part of the product, etc. The sliding system of the present invention may also be referred to as a sliding structure, a sliding machine (e.g. engine, transmission), or other appropriate term.

It suffices that the coating surface of the chromium nitride film according to the present invention is formed as a sliding surface of at least one of the sliding members which relatively move while facing each other. As will be understood, when both of the sliding surfaces facing each other are provided as the coating surfaces of the chromium nitride films, this may be more preferred.

(2) Unless otherwise stated, a numerical range “x-y” as referred to in the present description includes the lower limit x and the upper limit y. Any numerical value included in various numerical values or numerical ranges described in the present description may be selected or extracted as a new lower or upper limit, and any numerical range such as “a-b” can thereby be newly provided using such a new lower or upper limit.

### BRIEF DESCRIPTION OF DRAWINGS

FIG. 1A is a set of profiles obtained using X-ray diffraction on chromium nitride films according to the samples.

FIG. 1B is an enlarged view of the X-ray diffraction profile of a chromium nitride film according to Sample 3.

FIG. 2A is a bar graph comparing friction coefficients according to the samples.

FIG. 2B is a bar graph comparing wear depths according to the samples.

FIG. 3 is a dispersion diagram illustrating the relationships between the surface roughness and the friction coefficient according to the samples.

FIG. 4 is a dispersion diagram illustrating the relationships between the relative surface area and the friction coefficient according to the samples.

FIG. 5 is a graph illustrating the relationships between the Mo amount of Mo-DTP and the friction coefficient according to Sample 3 and Sample C1.

FIG. 6 is a schematic diagram illustrating an example of the molecular structure of Mo-DTP (R: alkyl group).

### DESCRIPTION OF EMBODIMENTS

One or more features freely selected from the present description may be added to the above-described features of the present invention. The contents described in the present description may be applied not only to the sliding system as a whole of the present invention but also to sliding members and a lubricant oil which constitute the sliding system.

### «Lubricant Oil»

The lubricant oil according to the present invention is not limited in the type of a base oil and the presence or absence of other additives, etc., provided that the lubricant oil contains Mo-DTP (see FIG. 6). An unduly small amount of the Mo-DTP may make it difficult to exhibit the low-friction property while an unduly large amount of the Mo-DTP may not cause any problem. Note, however, that the total amount of the contained Mo may preferably be small because Mo is a kind of rare metal. In this context, the Mo-DTP according to the present invention preferably has a mass ratio of Mo to the lubricant oil as a whole of 125-800 ppm in an embodiment, 150-700 ppm in another embodiment, and 200-600 ppm in still another embodiment. When the mass ratio of Mo to the lubricant oil as a whole is represented in ppm, it will be denoted by “ppmMo” as appropriate. When the lubricant oil contains other Mo-based compounds and the like than the Mo-DTP, the upper limit of the Mo total amount of the other Mo-based compounds is preferably 400 ppmMo in an embodiment and 300 ppmMo in another embodiment to the lubricant oil as a whole.

The lubricant oil may contain one or more compounds other than the Mo-DTP. For example, the lubricant oil may contain one or more of the following compounds: a phosphorus compound having a mass ratio of P of 200-1500 ppm in an embodiment and 400-1200 ppm in another embodiment to the lubricant oil as a whole; a sulfur compound having a mass ratio of S of 500-3000 ppm in an embodiment and 1000-2700 ppm in another embodiment to the lubricant oil as a whole; a nitrogen compound having a mass ratio of N of 200-2000 ppm in an embodiment and 500-1500 ppm in another embodiment to the lubricant oil as a whole; and other appropriate compounds.

Examples of such phosphorus compounds include Zn-DTP and ester phosphate in addition to the Mo-DTP. Examples of the sulfur compounds include Zn-DTP and Ca-sulfonate in addition to the Mo-DTP. Examples of the nitrogen compounds include succinimide and oleylamine. Even in a lubricant oil that contains such compounds (oil-soluble compounds) in addition to the Mo-DTP, the Mo-DTP appears to act preferentially on the sliding surface (coating surface) of the chromium nitride film and contribute, for example, to the formation of a molybdenum sulfide compound (such as MoS₂) that can reduce the friction coefficient.

### «Chromium Nitride Film»

The method of forming the chromium nitride film according to the present invention is not limited. For example, a desired chromium nitride film can be efficiently formed using a physical vapor deposition (PVD) method, such as an arc ion plating (AIP) method or a sputtering (SP) method (in particular, an unbalanced magnetron sputtering (UBMS) method).

The AIP method is a method in which a metal target (vaporization source) is used as the cathode to cause arc discharge, for example, in a reactive gas (process gas) so that metal ions generated from the metal target react with the reactive gas particles to form a dense film on a surface to be coated to which a bias voltage (negative voltage) is applied. In an embodiment of the present invention, for example, the target may be metal Cr and the reactive gas may be N₂ gas. When forming a chromium nitride film that contains doped elements in addition to Cr and N, a target or a reactive gas that contains the doping elements may be used. The composition, structure, and other properties of the chromium nitride film can be controlled by adjusting the components of the target and/or the reactive gas and/or adjusting the gas pressure of the reactive gas. For example, the gas pressure of N₂ may be adjusted thereby to allow a single-layer film of CrN or a composite film of CrN and Cr₂N to be obtained.

The SP method is a method in which a voltage is applied between a target at the cathode side and a surface to be coated at the anode side, and inactive gas atom ions generated by glow discharge are made to collide with the target surface so that particles (atoms/molecules) released from the target are deposited to form a film on the surface to be coated. In an embodiment of the present invention, the sputtering is performed using metal Cr as the target and Ar gas as the inactive gas, for example, and the released Cr atoms (ions) can be reacted with N₂ gas thereby to form the chromium nitride film on a sliding surface.

### «Use Applications»

The sliding members according to the present invention are not limited in the type, form, sliding form, and other features, provided that the sliding members have sliding surfaces that relatively move while the lubricant oil is interposed therebetween. The sliding system provided with such sliding members is also not limited in its specific form and use applications and can be widely applied to various machines, apparatuses, and the like which require reduction of the sliding resistance and reduction of the machine loss due to sliding. For example, the sliding system of the present invention may preferably be utilized for a drive system unit (such as an engine or a transmission) for vehicles such as cars. Examples of the sliding members which constitute such a sliding system include: components, such as cams, valve lifters, followers, shims, valves, and valve guides, which constitute a dynamic valve system; pistons; piston rings; piston pins; crankshafts; gears; rotors; and rotor housings.

### EXAMPLES

### «Overview»

A number of materials under test (sliding members) coated with chromium nitride films and a number of lubricant oils compounded with various amounts of the Mo-DTP (oil-soluble molybdenum compound) were prepared, and a block-on-ring friction test was conducted while changing the combination thereof. The present invention will be more specifically described with reference to the results of the friction test.

### «Production of Samples»

### (1) Base Materials

A number of block-like base materials (6.3 mm×15.7 mm×10.1 mm) were prepared, each comprising a quenched steel material (JIS SUS440C). A surface (surface to be coated) of each base material was mirror-finished (surface roughness Ra: 0.08 μm).

A steel material (JIS SCM420) merely carburized was also prepared as a comparative sample coated with no chromium nitride film (Sample C1 in Table 1). The carburized surface (hardness of Hv 700) was also mirror-finished to the same surface roughness.

### (2) Formation of Chromium Nitride Films

Materials under test (Samples 1 to 5) were prepared by forming various chromium nitride films as listed in Table 1 on the surfaces of the above base materials. Formation of the chromium nitride films was performed using an arc ion plating (AIP) method or a sputtering (SP) method.

Formation of the films using the arc ion plating method was performed by generating arc discharge on a target of metal Cr in N₂ gas (reactive gas) having an adjusted pressure of 0.3 to 6 Pa. Formation of the O-containing chromium nitride film was performed using a mixture gas of N₂ gas and O₂ gas as the reactive gas. During this operation, the ratio of the amount of O was 0.1 vol % to the mixture gas as a whole.

Formation of the B-containing chromium nitride film was performed using a target of Cr—B alloy (Cr-5 mass % B).

Formation of the film using the sputtering method was performed by sputtering a target of metal Cr with Ar gas to react the released Cr atoms (ions) with N₂ gas. During this operation, the pressure of N₂ gas was 0.5 to 6 Pa.

### «Measurement and Analysis of Chromium Nitride Films»

### (1) Film Composition and Film Properties

The film composition of each sample was quantified using an EPMA (JXA-8200 available from JEOL Ltd). The film hardness was measured using a nanoindenter tester (TRIBOSCOPE available from Hysitron Corporation). The film thickness was specified from a wear trace obtained using Calotest available from CSM Instruments. The film composition and film properties thus obtained of each sample are also listed in Table 1. The surface profile (roughness) according to the present examples was measured using a white light interferometric non-contact surface profiler (NewView 5022 available from Zygo Corporation).

### (2) Film Structures

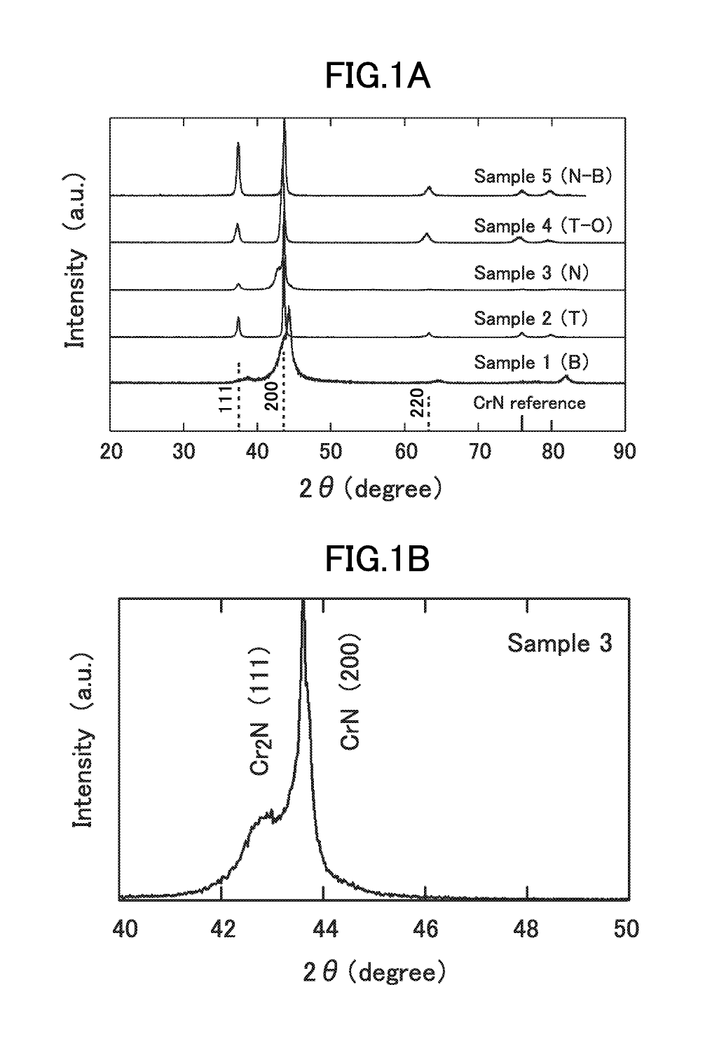

The chromium nitride film of each sample was analyzed with X-ray diffraction. Respective profiles thus obtained are illustrated in FIG. 1A in a superimposed manner. In addition, the profile according to Sample 3 is illustrated in FIG. 1B in an enlarged manner. FIG. 1A and FIG. 1B may be collectively referred to as FIG. 1 as appropriate.

The relative surface area of a (111) plane to a (200) plane was obtained in accordance with the previously-described method on the basis of each profile illustrated in FIG. 1. The relative surface area thus calculated of each sample is also listed in Table 1. As found from the profiles of the samples, Cr was not detected in all of the samples, and CrN was primarily detected. Note, however, that Cr₂N was detected in addition to CrN only in Sample 3. Presence or absence of the detection of Cr₂N is also listed in Table 1.

### «Lubricant Oils»

A number of prototype oils as listed in Table 2 were prepared assuming engine oils as the lubricant oils used in the friction test. Preparation of each prototype oil was performed through compounding a base oil (hydrocarbon-based base oil/YUBASE 8 available from SK Lubricants Co., Ltd.) with additives as listed in Table 1 and then heating and stirring at 60° C. for 30 minutes. Additives used herein are as follows:
Mo-DTP: ADEKA SAKURA-LUBE 300 available from ADEKA CORPORATION;
Zn-DTP (zinc dialkyldithiophosphate): 1371 available from Lubrizol Corporation (secondary alkyl type/anti-wear agent or antioxidant);
Overbased calcium sulfonate: 6477C available from Lubrizol Corporation (base number: 300 mg KOH); and
Polybutenyl succinimide: 6412 available from Lubrizol Corporation (ashless dispersant).

Representative amounts of elements contained in each prototype oil are also listed in Table 2. Each element content was adjusted so that the element contents of Mo, Zn, P, Ca, and N and the base number (overbased Ca-sulfonate) would be equivalent to those contained in a commonly used and commercially available engine oil and its properties.

### «Block-On-Ring Friction Test»

(1) Block-on-ring friction test (referred simply to as “friction test”) was performed for a combination of each material under test and the prototype oil D. The friction test was performed using each material under test as a block test piece having a sliding surface width of 6.3 mm and using a standard test piece S-10 (hardness of HV 800 and surface roughness of 1.7-2.0 μm Rzjis) of a carburized steel material (AISI4620) available from FALEX CORPORATION as a ring test piece (an outer diameter of φ35 mm and a width of 8.8 mm). The friction test was performed for 30 minutes under the condition of a test load of 133 N (Hertz contact pressure of 210 MPa), a sliding speed of 0.3 m/s, and an oil temperature of 40° C. (fixed), and the average value of μ for one minute immediately before completion of the test was determined as the friction coefficient of each sliding surface.

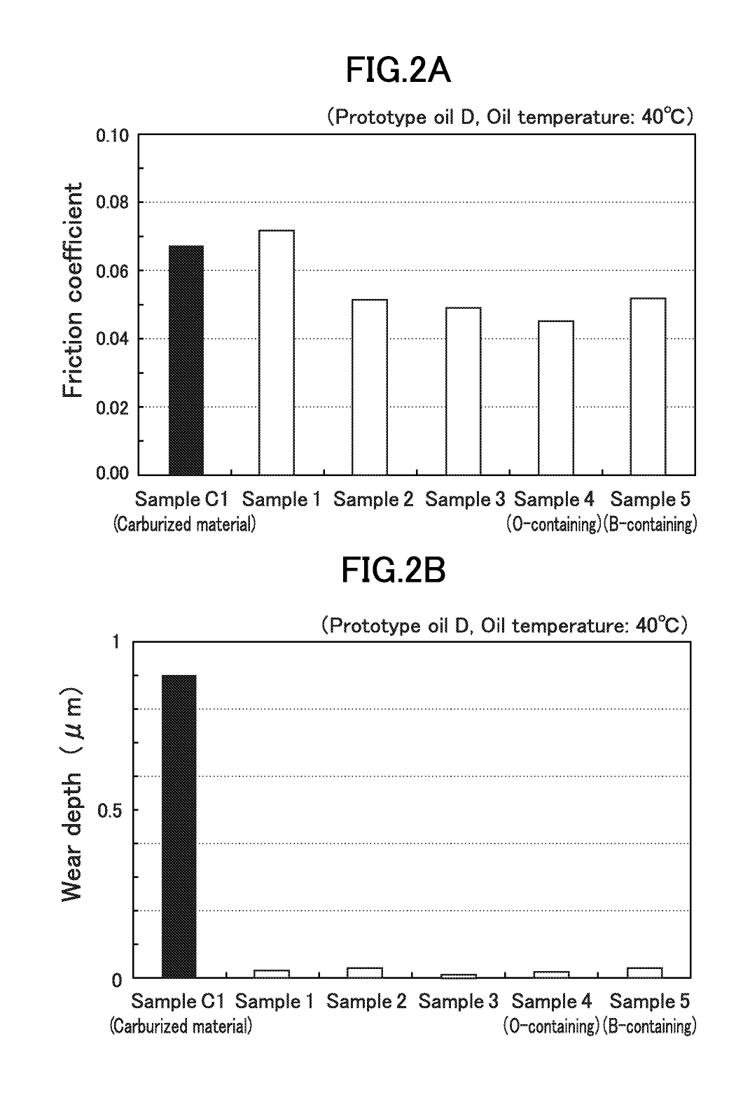

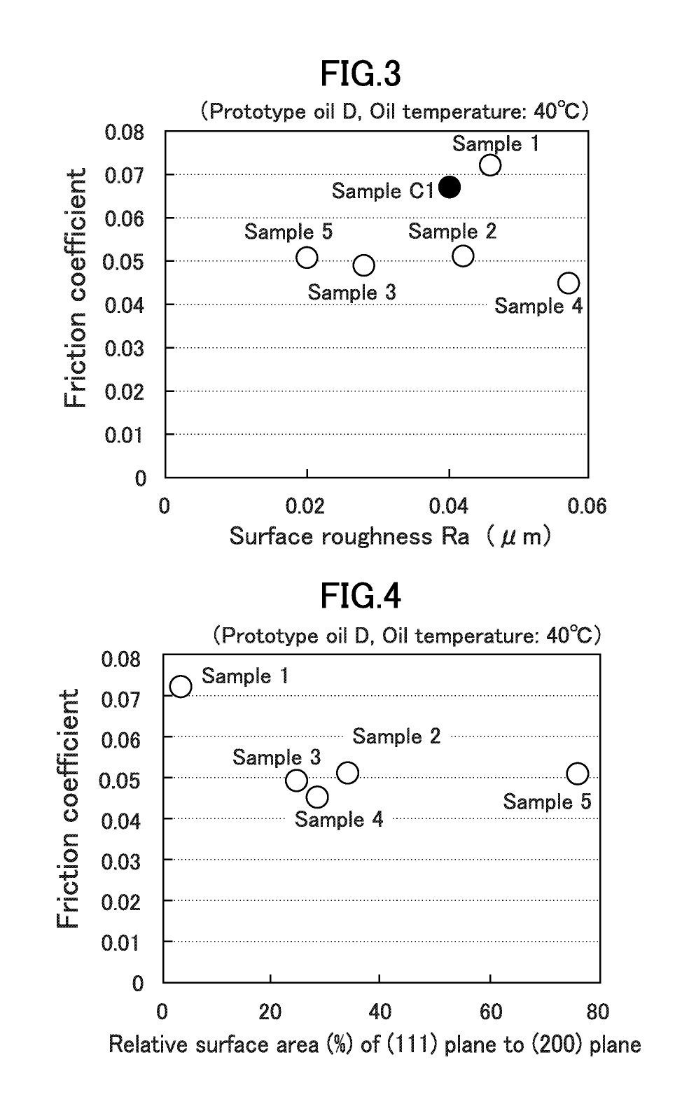

FIG. 2A illustrates a bar graph comparing the friction coefficients of the materials under test. In addition, the sliding surface of each material under test after the friction test was measured using the previously-described non-contact surface profiler to obtain the wear depth and the surface roughness. FIG. 2B illustrates a bar graph comparing the wear depths of the materials under test and FIG. 3 illustrates the relationship between the surface roughness and the friction coefficient according to each material under test. FIG. 4 illustrates the relationship between the friction coefficient of each material under test and the relative surface area of a (111) plane to a (200) plane of the chromium nitride film of each material under test.

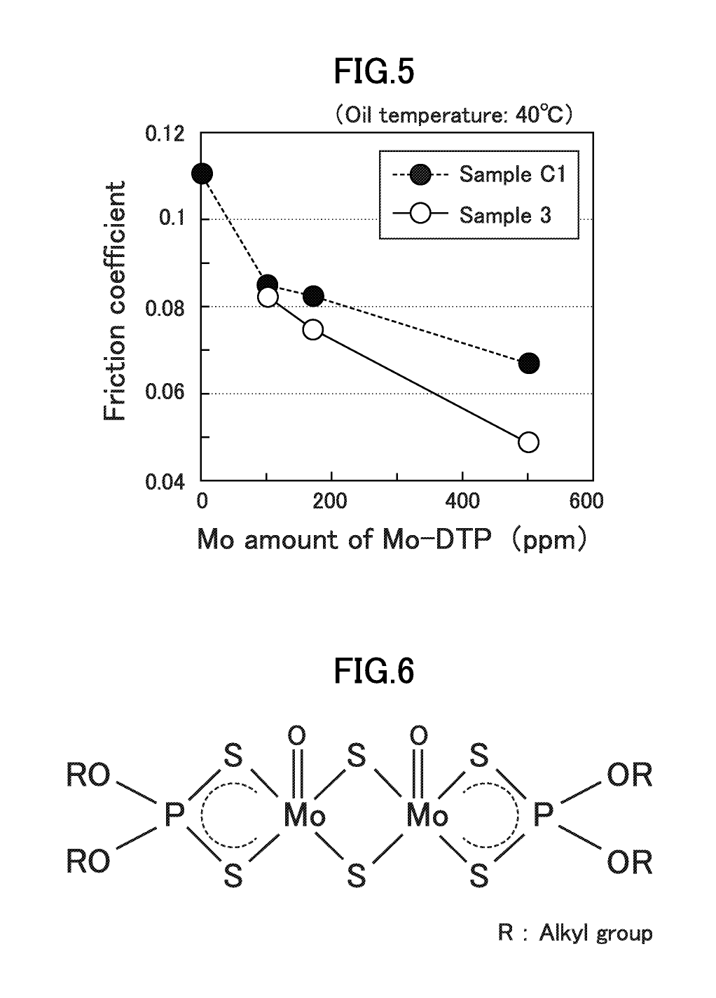

(2) Likewise, the above-described friction test was performed for a combination of the material under test of Sample 3 or C1 and any of the prototype oils A to D to obtain the friction coefficient in each case. FIG. 5 illustrates the relationship between the Mo amount of Mo-DTP added to each prototype oil and the friction coefficient of each material under test.

### «Evaluation»

### (1) Friction Property

As apparent from FIG. 2A, when using the lubricant oil containing the Mo-DTP (Mo amount: 500 ppm), the friction coefficients of Samples 2 to 5 are all lower than that of Sample C1 even though the oil temperature is a low value of 40° C. As apparent from FIG. 2B, it has also been confirmed that all of Samples 2 to 5 have considerably smaller wear depths than that of Sample C1 and exhibit excellent wear resistance.

### (2) Surface Roughness

As apparent from FIG. 3, no particular correlation is found between the surface roughness of the sliding surface and the friction coefficient and it cannot be said that the sliding surfaces of Samples 2 to 5 exhibiting low-friction properties are especially smooth. Thus, it cannot be considered that the low-friction properties of Samples 2 to 5 are caused by the smoothened sliding surfaces.

### (3) Structure of Chromium Nitride Film

As apparent from FIG. 4, it has been found that Samples 2 to 5 exhibiting low-friction properties each have a larger relative surface area of a (111) plane to a (200) plane of the chromium nitride film than that of Sample 1 which does not exhibit a low-friction property. That is, it has been found that the low-friction properties are developed in chromium nitride films in which the (111) planes are mixed to some extent (15% or more, for example) rather than in the chromium nitride film in which the orientation of the (200) planes is strong. This appears to be because the chromium nitride films having the relative surface areas of a certain value or more are more likely to form sulfur compounds of Mo on the films due to competitive adsorption of the Mo-DTP and other oil additives.

### (4) Amount of Mo-DTP (Mo Equivalent)

As apparent from FIG. 5, when the amount of Mo-DTP is unduly small, the friction coefficients of Sample 3 and Sample C1 are comparable. However, it has been found that, when the Mo-DTP is 125 ppm or more and further 150 ppm or more as the Mo amount, Sample 3 having a specific chromium nitride film clearly develops a low-friction property unlike Sample C1.

### (5) Consideration

From the above results, it has been revealed that the low-friction property is developed even in a low-temperature region by combining a chromium nitride film having a specific structure in which the relative surface area of a (111) plane to a (200) plane is a predetermined value or more and a lubricant oil that contains a predetermined amount or more of Mo-DTP. This appears to be because the Mo-DTP adsorbs to or reacts with the sliding surface of a specific chromium nitride film to form a molybdenum sulfide compound (such as MoS₂) that develops a low shear property. That is, it can be considered that the boundary friction coefficient when the molybdenum sulfide compound directly contacts the sliding surface is reduced and, accordingly, the friction coefficient of the entire macro contact part is also reduced.

TABLE 1

| | | | | | | | | | Film structure | | | | |
|---|---|---|---|---|---|---|---|---|---|---|---|---|---|
| | | | | | | | | | (Results of X-ray diffraction) | | | | |
| | | | | | | | Film properties | | Relative surface | | | | |
| | | | Film composition | | | | Film | Film | area | | | | |
| Sample | | Production | (at %) | | | | hardness | thickness | (111)/(200) | | | | |
| No. | Name | method | Cr | N | O | B | (GPa) | (μm) | (%) | Cr₂N | CrN | Cr | Note |
| 1 | B | SP method | 62.4 | 37.6 | — | — | 24.1 | 2 | 3.4 | — | Δ | — | |
| 2 | T | AIP method | 50.7 | 49.3 | — | — | 16.9 | 13 | 34 | — | ◯ | — | |
| 3 | N | | 60.9 | 39.1 | — | — | 21.5 | 8 | 24.7 | ◯ | ◯ | — | |
| 4 | T—O | | 49.7 | 40.5 | 9.8 | — | 22.4 | 13 | 28.5 | — | ◯ | — | |
| 5 | N—B | | 48.7 | 50.0 | — | 1.3 | 21.0 | 9 | 75.8 | — | ◯ | — | |

| | | | | | | | |
|---|---|---|---|---|---|---|---|
| C1 | (Carburized | — | — | (HV700) | — | — | SCM |
| | material) | | | | | | 420 |

“—,” “◯,” and “Δ” listed in the results of X-ray diffraction are as follows:
—: Peaks are substantially absent./◯: Strong peaks are present./Δ: Week peaks are present.

TABLE 2

| | Compounding amount of additives | | | | | | | | | |
|---|---|---|---|---|---|---|---|---|---|---|
| | (the balance: base oil) (mass %) | | | | | | | | | |
| | | | Overbased | | | | | | | |
| Name of | | | calcium | Polybutenyl | Element content (ppm) | | | | | |
| prototype oil | Mo-DTP | Zn-DTP | sulfonate | succinimide | Mo | S | P | Zn | Ca | N |
| A | 0 | 0.8 | 2.0 | 6.0 | 0 | 2036 | 800 | 884 | 2400 | 900 |
| B | 0.11 | | | | 100 | 2147 | 835 | 884 | 2400 | 900 |
| C | 0.19 | | | | 171 | 2228 | 861 | 884 | 2400 | 900 |
| D | 0.56 | | | | 500 | 2602 | 979 | 884 | 2400 | 900 |

1. A sliding system comprising:
a pair of sliding members having sliding surfaces that can relatively move while facing each other; and
a lubricant oil that can be interposed between the sliding surfaces facing each other,
at least one of the sliding surfaces comprising a coating surface of a chromium nitride film,
the chromium nitride film comprising, when the film as a whole is 100 at % (referred simply to as “%”), 40-65% of Cr and 35-55% of N and having a relative surface area of 15-85%, the relative surface area being a surface area ratio of a (111) plane to a (200) plane obtained when analyzed with X-ray diffraction,
the lubricant oil containing molybdenum dialkyldithiophosphate (referred simply to as “Mo-DTP”) that is an oil-soluble molybdenum compound,
the Mo-DTP being contained at 125-800 ppm as a mass ratio of Mo with respect to the lubricant oil as a whole.

2. The sliding system as recited in claim 1, wherein the chromium nitride film further comprises 1-15% of O or 0.5-5% of B.

3. The sliding system as recited in claim 1, wherein the chromium nitride film contains Cr₂N together with CrN.

4. The sliding system as recited in claim 1, wherein the lubricant oil contains one or more of a phosphorus compound having a mass ratio of P of 200-1500 ppm to the lubricant oil as a whole, a sulfur compound having a mass ratio of S of 500-3000 ppm to the lubricant oil as a whole, and a nitrogen compound having a mass ratio of N of 200-2000 ppm to the lubricant oil as a whole.

5. The sliding system as recited in claim 1, wherein the sliding system is an internal-combustion engine for hybrid cars or a drivetrain including a transmission.
